(19) United States
(12) Patent Application Publication
(10) Pub. No.: US 2026/0334097 A1
(43) Pub. Date: Oct. 22, 2026

(54) OXYGEN AFFINITY LAYER TO IMPROVE RRAM CELL PERFORMANCE

(71) Applicant: Taiwan Semiconductor Manufacturing Company, Ltd., Hsinchu (TW)

(72) Inventors: Fa-Shen Jiang, Taoyuan City (TW); Hai-Dang Trinh, Hsinchu (TW); Cheng-Yuan Tsai, Chu-Pei City (TW); Chung-Yi Yu, Hsin-Chu (TW)

(21) Appl. No.: 19/723,567

(22) Filed: Jun. 29, 2026

Related U.S. Application Data
(62) Division of application No. 18/425,333, filed on Jan. 29, 2024.
(60) Provisional application No. 63/501,747, filed on May 12, 2023.

(51) Int. Cl. H10N 70/20; H10B 63/00; H10N 70/00

(52) U.S. Cl. CPC H10N 70/24; H10B 63/30; H10N 70/021; H10N 70/063; H10N 70/068; H10N 70/841; H10N 70/8833

(57) ABSTRACT

Various embodiments of the present disclosure are directed towards an integrated chip including a bottom electrode over a substrate. A top electrode overlies the bottom electrode. A capping structure is disposed between the top electrode and the bottom electrode. The capping structure comprises a diffusion barrier layer vertically stacked with a metal layer. A switching structure is disposed between the bottom electrode and the capping structure. The switching structure comprises a dielectric layer on the bottom electrode and a first oxygen affinity layer on the dielectric layer. A first Gibbs free energy of the first oxygen affinity layer is less than a second Gibbs free energy of the dielectric layer. A first difference between the first Gibbs free energy and the second Gibbs free energy is less than −100 kJ/mol.

### REFERENCE TO RELATED APPLICATIONS

This Application is a Divisional of U.S. Application number Ser. No. 18/425,333, filed on Jan. 29, 2024, which claims the benefit of U.S. Provisional Application number 63/501,747, filed on May 12, 2023. The contents of the above-referenced Patent Applications are hereby incorporated by reference in their entirety.

### BACKGROUND

Many modern electronic devices contain electronic memory configured to store data. Electronic memory may be volatile memory or non-volatile memory. Volatile memory stores data while it is powered, while non-volatile memory is able to keep data when power is removed. Resistive random-access memory (RRAM) is one promising candidate for next generation non-volatile memory technology due to its simple structure and compatibility with complementary metal-oxide semiconductor (CMOS) logic processes. An RRAM cell includes a switching structure having a variable resistance. Such a switching structure is generally placed between two electrodes disposed within interconnect metallization layers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of an integrated chip comprising a resistive random-access memory (RRAM) cell having an oxygen affinity layer over a dielectric layer.

FIG. 2 illustrates a cross-section view of some embodiments of an RRAM cell comprising an oxygen affinity layer over a dielectric layer.

FIG. 3 illustrates a cross-sectional view of some embodiments of an integrated chip comprising an RRAM cell having an oxygen affinity layer over a dielectric layer.

FIG. 4 illustrates a cross-sectional view of some other embodiments of the integrated chip of FIG. 3.

FIG. 5 illustrates a cross-sectional view of some other embodiments of the integrated chip of FIG. 4, where the RRAM cell further comprises an upper oxygen affinity layer over the oxygen affinity layer.

FIG. 6 illustrates a cross-sectional view of some embodiments of an integrated chip comprising a memory region laterally adjacent to a logic region.

FIG. 7 illustrates a cross-sectional view of some other embodiments of an integrated chip comprising RRAM cells that respectively comprise an oxygen affinity layer over a dielectric layer.

FIG. 8 illustrates a cross-sectional view of some embodiments of an integrated chip comprising an RRAM cell disposed within an interconnect structure over a substrate.

FIGS. 9-14 illustrate cross-sectional views of some embodiments of a method for forming an integrated chip including an RRAM cell comprising a switching layer having an oxygen affinity layer stacked with a dielectric layer.

FIGS. 15-21 illustrate cross-sectional views of some other embodiments of a method for forming an integrated chip including an RRAM cell comprising a switching layer having an oxygen affinity layer stacked with a dielectric layer.

FIG. 22 illustrates a flowchart that illustrates some embodiments of a method for forming an integrated chip including an RRAM cell comprising a switching layer having an oxygen affinity layer stacked with a dielectric layer.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Integrated chips may include resistive random-access memory (RRAM) cells that include a switching structure disposed between a top electrode and a bottom electrode. A variable resistance of the switching structure represents a data unit, such as a bit of data. Depending on a voltage applied between the top and bottom electrodes, the variable resistance undergoes a reversible change between a high resistance state and a low resistance state corresponding to data states of the data unit. The high resistance state is high in that the variable resistance exceeds a threshold and the low resistance state is low in that the variable resistance is below the threshold.

Before an RRAM cell is used to store data, an initial conductive path (i.e., conductive filament) is typically formed across the switching structure. Formation of the initial conductive path makes subsequent write operations (that form the conductive path) easier to perform. The initial conductive path is formed by applying a forming voltage across the top and bottom electrodes. In some types of RRAM cells, the conductive path may include vacancies (e.g., oxygen vacancies). In such devices the forming voltage may break bonds in the switching structure, thereby knocking oxygen atoms out of a lattice of the switching structure and forming localized oxygen vacancies. These localized oxygen vacancies tend to align to form the conductive path, which extends through the switching structure. Thereafter, set or rest voltages can be applied across the top and bottom electrodes to change resistivity of the switching structure. A capping structure is disposed between the top electrode and the switching structure, where the capping structure comprises a metal layer contacting the switching structure. The capping structure is configured to receive oxygen ions from the switching structure or provide oxygen ions to the switching structure during operation of the RRAM cell (e.g., during formation, set, and/or rest operations).

In some instances, the switching structure may comprise a single dielectric layer comprising a dielectric material (e.g., tantalum oxide). The forming voltage of such a configuration may be relatively high because oxygen ions may not migrate from the dielectric material until application of the forming voltage. The relatively high forming voltage becomes problematic as feature sizes of the integrated chip scale down because the relatively high forming voltage may be greater than a safe output voltage of scaled transistors utilized to apply the forming voltage. Further, in an effort to reduce the forming voltage, a thickness of the single dielectric layer may be reduced (e.g., to below 10 angstroms), however this may increase a leakage current of the RRAM cell (e.g., from electron tunneling across the switching structure) and may decrease a reliability of the RRAM cell. Furthermore, after performing a forming operation or a set operation, oxygen ions that migrated from the switching structure to the capping structure may be prone to diffusing back to the switching structure. This may result in dissolving at least a portion of the conductive path. As a result, discrete data states of the RRAM cell may not be properly maintained and/or read, thereby reducing an overall performance of the RRAM cell.

The present disclosure, in some embodiments, is directed towards an RRAM cell that has a switching structure comprising an oxygen affinity layer over a dielectric layer. The dielectric layer overlies a bottom electrode and the oxygen affinity layer is disposed on the dielectric layer. A capping structure is disposed between the oxygen affinity layer and a top electrode. The dielectric layer comprises a first dielectric material (e.g., tantalum oxide) and the oxygen affinity layer comprises a second dielectric material (e.g., zirconium oxide) different from the first dielectric material. A Gibbs free energy of the oxygen affinity layer is less than a Gibbs free energy of the dielectric layer. As a result, the oxygen affinity layer has a greater tendency to react with oxygen than the dielectric layer, such that oxygen ions may migrate from the dielectric layer to the oxygen affinity layer before performing a forming operation. This intrinsic migration of oxygen ions from the dielectric layer to the oxygen affinity layer forms intrinsic oxygen vacancies in at least the dielectric layer before applying a forming voltage. In addition, a thickness of the dielectric layer is greater than or equal to that of the oxygen affinity layer such that a sufficient number of oxygen ions may migrate from the dielectric layer to the oxygen affinity layer. This facilitates a sufficient number of intrinsic oxygen vacancies being formed in the dielectric layer to sufficiently reduce the forming voltage. Thus, the oxygen affinity layer decreases the forming voltage (e.g., to about 2.3V), thereby decreasing a power consumption of the RRAM cell, decreasing damage to the RRAM cell and/or transistors used to apply the forming voltage, and increases a reliability of the RRAM cell.

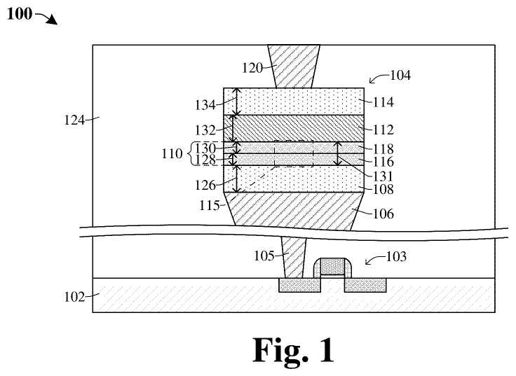

FIG. 1 illustrates a cross-sectional view 100 of some embodiments of an integrated chip including a resistive random-access memory (RRAM) cell 104 that has a switching structure 110 comprising a dielectric layer 116 and an oxygen affinity layer 118.

The integrated chip includes a transistor 103 disposed on a substrate 102 and the RRAM cell 104 overlying the substrate 102. In some embodiments, the transistor 103 is configured as a metal-oxide-semiconductor field-effect transistor (MOSFET) or some other suitable transistor. A dielectric structure 124 comprising one or more dielectric materials overlies the substrate 102. The RRAM cell 104 is disposed within the dielectric structure 124. Further, one or more conductive structures are disposed within the dielectric structure 124 and are configured to electrically couple the transistor 103 to the RRAM cell 104. For example, the transistors 103 may be electrically coupled to the RRAM cell 104 by way of a conductive contact 105 and a lower conductive wire 106. An upper conductive structure 120 is disposed within the dielectric structure 124 and overlies the RRAM cell 104. In various embodiments, the transistor 103 may be configured to supply and/or facilitate supplying suitable bias conditions to the RRAM cell 104, such that the RRAM cell 104 is switched between two states of electrical resistance, a low resistance state and a high resistance state, to store data.

In some embodiments, the RRAM cell 104 includes: a bottom electrode 108, the switching structure 110 over the bottom electrode 108, a capping structure 112 overlying the switching structure 110, and a top electrode 114 over the capping structure 112. The switching structure 110 comprises the dielectric layer 116 disposed along the bottom electrode 108 and the oxygen affinity layer 118 disposed along the dielectric layer 116. In various embodiments, the dielectric layer 116 and the oxygen affinity layer 118 comprise material(s) having a variable resistance configured to undergo a reversible change between a high resistance state and a low resistance state. The dielectric layer 116 comprises a first dielectric material (e.g., tantalum oxide) and the oxygen affinity layer comprises a second dielectric material (e.g., zirconium oxide) different from the first dielectric material. In some embodiments, a Gibbs free energy of the oxygen affinity layer 118 is less than a Gibbs free energy of the dielectric layer 116. As a result, the oxygen affinity layer 118 has a greater tendency to react with oxygen than the dielectric layer 116. In various embodiments, a difference between the Gibbs free energy of the oxygen affinity layer 118 and the Gibbs free energy of the dielectric layer 116 is less than or equal to −100 kJ/mol.

In various embodiments, before the RRAM cell 104 may be used to store data, an initial conductive path (i.e., conductive filament) is typically formed within a region 115 across the switching structure 110. Formation of the initial conductive path makes subsequent write operations (e.g., that form the conductive path) performed on the RRAM cell 104 easier to perform. The initial conductive path comprises oxygen vacancies that are disposed within the region 115 and extend from a top surface of the bottom electrode 108 to a bottom surface of the capping structure 112. Typically, forming the initial conductive path includes applying a forming voltage across the bottom and top electrodes 108, 114 by way of the transistor 103 and the upper conductive structure 120. The forming voltage may knock oxygen atoms out of a lattice of the layers in the switching structure 110, thereby forming localized oxygen vacancies that tend to align in the region 115 to form the initial conductive path. Thereafter, set or reset voltages can be applied across the bottom and top electrodes 108, 114 to change a resistivity of the switching structure 110 between the high resistance state and the low resistance state.

By virtue of the RRAM cell 104 comprising the oxygen affinity layer 118 between the dielectric layer 116 and the capping structure 112, the forming voltage may be reduced (e.g., to below 2.3V) and/or the forming process may be eliminated. This occurs because of the difference of the Gibbs free energy of the oxygen affinity layer 118 and the dielectric layer 116. The oxygen affinity layer 118 is more likely to react with oxygen then the dielectric layer 116, such that oxygen ions may migrate from the dielectric layer 116 to the oxygen affinity layer 118. The intrinsic migration of the oxygen ions to the oxygen affinity layer 118 results in a formation of intrinsic oxygen vacancies (not shown) in the dielectric layer 116 before performing the forming process and a write operation on the RRAM cell 104. The presence of the intrinsic oxygen vacancies in the dielectric layer 116 reduces the forming voltage and/or may eliminate the forming process, such that write operations may be performed on the RRAM cell 104 without performing the forming process first. As a result, a power consumption of the integrated chip is reduced, a size of the transistor 103 may be scaled down, and/or reliability of the RRAM cell 104 is increased. Thus, the RRAM cell 104 comprising the oxygen affinity layer 118 between the dielectric layer 116 and the capping structure 112 increases an overall performance of the RRAM cell 104.

In various embodiments, a thickness 128 of the dielectric layer 116 is greater than or equal to a thickness 130 of the oxygen affinity layer 118. For example, a ratio between the thickness 130 and the thickness 128 is within a range of about 0.85 to 1 or some other suitable value. In various embodiments, the ratio between the thicknesses 130, 128 being 1 or less (i.e., the dielectric layer 116 being at least as thick as the oxygen affinity layer 118) facilitates a sufficient number of oxygen ions migrating from the dielectric layer 116 to the oxygen affinity layer 118 to form the intrinsic oxygen vacancies in the dielectric layer 116. In yet further embodiments, the ratio between the thicknesses 130, 128 being 0.85 or greater facilitates the oxygen affinity layer 118 being sufficiently thick to receive a sufficient number of oxygen ions from the dielectric layer 116. Further, a thickness 131 of the switching structure 110 is less than a thickness 126 of the bottom electrode 108, less than a thickness 132 of the capping structure 112, and less than a thickness 134 of the top electrode 114.

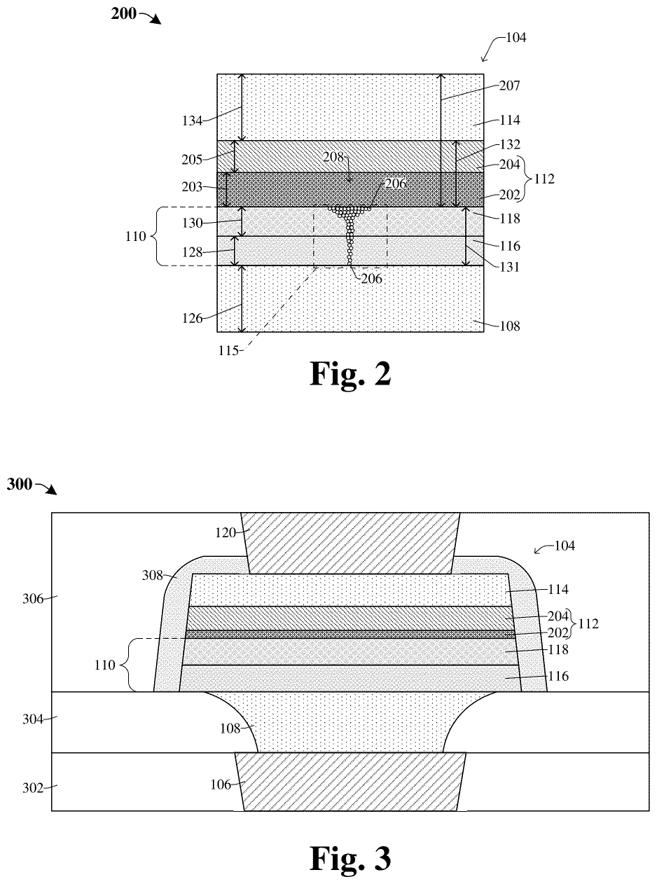

FIG. 2 illustrates a cross-sectional view 200 of some embodiments of an RRAM cell 104 comprising an oxygen affinity layer 118 over a dielectric layer 116. In some embodiments, the cross-sectional view 200 corresponds to a more detailed breakout of the layers in the RRAM cell 104 of FIG. 1.

The RRAM cell 104 comprises a bottom electrode 108, a switching structure 110, a capping structure 112, and a top electrode 114. In various embodiments, the switching structure 110 comprises the dielectric layer 116 and the oxygen affinity layer 118. The dielectric layer 116 directly contacts the bottom electrode 108 and the oxygen affinity layer 118 overlies and directly contacts the dielectric layer 116. In some embodiments, the capping structure 112 comprises a diffusion barrier layer 202 and a metal layer 204. The diffusion barrier layer 202 is disposed directly between the metal layer 204 and the oxygen affinity layer 118. Further the top electrode 114 directly overlies the metal layer 204.

In various embodiments, during operation the RRAM cell 104 relies on redox reactions to form and dissolve a conductive path 208 in a region 115 of the switching structure 110 between the bottom electrode 108 and the capping structure 112. The existence of the conductive path 208 in the region 115 produces a low resistance state, while an absence of at least a portion of the conductive path 208 along the thickness 131 of the switching structure 110 results in a high resistance state. Thus, the RRAM cell 104 can be switched between the high resistance state and the low resistance state by applying appropriate biases to the RRAM cell 104 to produce or dissolve the conductive path 208 in the region 115. In various embodiments, the conductive path 208 may, for example, include oxygen vacancies 206 disposed within the region 115 and extending between the bottom electrode 108 and the capping structure 112.

In various embodiments, during write operations performed on the RRAM cell 104, the metal layer 204 of the capping structure 112 is configured to receive oxygen ions from the switching structure 110 and/or provide oxygen ions to the switching structure 110. This facilitates the formation and dissolution of the conductive path 208 in the region 115. Further, oxygen ions in the metal layer 204 may be prone to diffusing out of the metal layer 204 to the oxygen affinity layer 118 after forming the conductive path 208. By virtue of a material and thickness 203 of the diffusion barrier layer 202, the diffusion of oxygen ions is mitigated when bias voltages are not applied across the RRAM cell 104. Thus, the diffusion barrier layer 202 is configured to mitigate undesired diffusion of oxygen ions between the oxygen affinity layer 118 and the metal layer 204. This, in part, increases discrete data states of the RRAM cell 104, thereby increasing an overall performance of the RRAM cell 104.

In some embodiments, the dielectric layer 116 may, for example, be or comprise titanium oxide (e.g., TiO), tantalum oxide (e.g., Ta₂O₅), titanium dioxide (e.g., TiO₂), silicon dioxide (e.g., SiO₂), Zinc Oxide (e.g., ZnO), or some other suitable dielectric material. In further embodiments, the oxygen affinity layer 118 may, for example, be or comprise zirconium dioxide (e.g., ZrO₂), lanthanum oxide (e.g., La₂O₃), neodymium oxide (e.g., Nd₂O₃), gadolinium oxide (e.g., Gd₂O₃), Yttrium Oxide (e.g., Y₂O₂), or some other suitable dielectric material. In various embodiments, a Gibbs free energy of the dielectric layer 116 is greater than at least −1000 kJ/mol and a Gibbs free energy of the oxygen affinity layer 118 is less than at least −1000 kJ/mol. Further, a difference between the Gibbs free energy of the oxygen affinity layer 118 and the Gibbs free energy of the dielectric layer 116 is less than or equal to −100 kJ/mol, less than −250 kJ/mol, less than −500 kJ/mol, or the like. In such embodiments, the difference being less than or equal to −100 kJ/mol facilitates oxygen ions migrating from the dielectric layer 116 to the oxygen affinity layer 118. In various embodiments, at least a portion of the oxygen vacancies 206 are formed and/or disposed in the dielectric layer 116 as a result of the intrinsic migration of the oxygen ions from the dielectric layer 116 to the oxygen affinity layer 118.

In various embodiments, a thickness 128 of the dielectric layer 116 is greater than or equal to a thickness 130 of the oxygen affinity layer 118. For example, a ratio between the thickness 130 and the thickness 128 is within a range of about 0.85 to 1 or some other suitable value. The thickness 128 of the dielectric layer 116 is, for example, within a range of about 10 to 15 angstroms or some other suitable value. The thickness 130 of the oxygen affinity layer 118 is, for example, within a range of about 10 to 15 angstroms or some other suitable value. In various embodiments, the thicknesses 128, 130 of the dielectric layer 116 and the oxygen affinity layer 118 respectively being equal to or greater than about 10 angstroms mitigates electron tunneling between the top electrode 114 and the bottom electrode 108, thereby mitigating leakage current and/or increasing discrete data states. In further embodiments, the thicknesses 128, 130 of the dielectric layer 116 and the oxygen affinity layer 118 respectively being equal to or less than about 15 angstroms reduces the forming voltage and/or writing voltage of the RRAM cell 104.

The bottom electrode 108 may, for example, be or comprise titanium nitride, tantalum nitride, tantalum, titanium, platinum, nickel, hafnium, zirconium, ruthenium, iridium, some other suitable conductive material, or any combination of the foregoing. The diffusion barrier layer 202 may, for example, be or comprise tantalum nitride, titanium nitride, hafnium nitride, zirconium nitride, some other suitable material, or any combination of the foregoing. The metal layer 204 may, for example, be or comprise tantalum, titanium, hafnium, zirconium, some other suitable material, or any combination of the foregoing. In various embodiments, the diffusion barrier layer 202 is a metal nitride of the metal layer 204. For example, the diffusion barrier layer 202 may be or comprise titanium nitride and the metal layer 204 may be or comprise titanium. The top electrode 114 may, for example, be or comprise titanium nitride, tantalum nitride, tantalum, titanium, platinum, nickel, hafnium, zirconium, ruthenium, iridium, some other suitable conductive material, or any combination of the foregoing.

The thickness 203 of the diffusion barrier layer 202 is, for example, within a range of about 20 to 30 angstroms or some other suitable value. In some embodiments, the thickness 203 of the diffusion barrier layer 202 is greater than the thickness 130 of the oxygen affinity layer 118 and is greater than the thickness 128 of the dielectric layer 116. In various embodiments, a ratio between the thickness 203 of the diffusion barrier layer 202 and the thickness 130 of the oxygen affinity layer 118 is within a range of about 2 to 3 or some other suitable value. A thickness 205 of the metal layer 204 is, for example, within a range of about 10 to 50 angstroms or some other suitable value. A thickness 134 of the top electrode 114 is, for example, within a range of about 80 to 195 angstroms or some other suitable value. A thickness 126 of the bottom electrode 108 is, for example, within a range of about 75 to 90 angstroms or some other suitable value. In various embodiments, the thickness 134 of the top electrode 114 is greater than the thickness 126 of the bottom electrode 108.

In various embodiments, a ratio between the thickness 131 of the switching structure 110 and the thickness 132 of the capping structure 112 is within a range of about 0.6 to 1 or some other suitable value. In yet further embodiments, a ratio between the thickness 131 of the switching structure 110 and a thickness 207 of the capping structure 112 and the top electrode 114 is within a range of about 0.1 to 0.2 or some other suitable value. In various embodiments, the ratio between the thicknesses 131 and 207 being equal to or greater than 0.1 facilitates the switching structure 110 being sufficiently thick to mitigate leakage current. In further embodiments, the ratio between the thicknesses 131 and 207 being equal to or less than 0.2 facilitates the switching structure 110 being sufficiently thin to reduce the forming voltage and write voltage, thereby decreasing a power consumption of the RRAM cell 104 and facilitating the scaling of transistors used to apply bias voltages to the RRAM cell 104. In some embodiments, a ratio between the thickness 131 of the switching structure 110 and the thickness 126 of the bottom electrode 108 is within a range of about 0.2 to 0.3 or some other suitable value.

FIG. 3 illustrates a cross-sectional view 300 of some embodiments of an integrated chip including an RRAM cell 104 having an oxygen affinity layer 118 over a dielectric layer 116. In various embodiments, the RRAM cell 104 is configured as illustrated and/or described in FIG. 2.

The integrated chip includes the RRAM cell 104 overlying a lower conductive wire 106 disposed within a first inter-metal dielectric (IMD) layer 302. A lower dielectric layer 304 overlies the first IMD layer 302 and a second IMD layer 306 overlies the lower dielectric layer 304. The lower conductive wire 106 is electrically coupled to the RRAM cell 104. The first and second IMD layers 302, 306 may, for example, be or comprise silicon dioxide, a low-k dielectric material such as undoped silica glass (USG) or carbon-doped silicon dioxide, some other suitable dielectric material, or any combination of the foregoing. The lower dielectric layer 304 may, for example, be or comprise silicon carbide, silicon oxycarbide, silicon nitride, silicon oxynitride, some other suitable dielectric material, or any combination of the foregoing.

In some embodiments, the RRAM cell 104 comprises a bottom electrode 108, a switching structure 110 over the bottom electrode 108, a capping structure 112 over the switching structure 110, and a top electrode 114 over the capping structure 112. The switching structure 110 comprises the dielectric layer 116 disposed on the bottom electrode 108 and the oxygen affinity layer 118 disposed on the dielectric layer 116. In various embodiments, a Gibbs free energy of the oxygen affinity layer 118 is less than a Gibbs free energy of the dielectric layer 116. In further embodiments, the dielectric layer 116 and the first IMD layer 302 and/or the second IMD layer 306 respectively comprise a same dielectric material (e.g., silicon dioxide). In further embodiments, the oxygen affinity layer 118 comprises a high-k dielectric material (e.g., having a dielectric constant greater than about 3.9). The capping structure 112 comprises a diffusion barrier layer 202 directly contacting the oxygen affinity layer 118 and a metal layer 204 directly contacts the diffusion barrier layer 202. The top electrode 114 directly overlies the metal layer 204. Further, a sidewall spacer structure 308 continuously extends along opposing sidewalls of the RRAM cell 104. An upper conductive structure 120 overlies the top electrode 114. The lower conductive wire 106 and the upper conductive structure 120 may, for example, be or comprise aluminum, copper, tungsten, ruthenium, titanium nitride, some other suitable conductive material, or any combination of the foregoing.

In various embodiments, opposing sidewalls of the dielectric layer 116, the oxygen affinity layer 118, the diffusion barrier layer 202, the metal layer 204, and the top electrode 114 are respectively aligned with one another. Further, the bottom electrode 108 is spaced between the opposing sidewalls of the dielectric layer 116. The sidewall spacer structure 308 continuously extends along the opposing sidewalls of the RRAM cell 104 to a top surface of the RRAM cell 104.

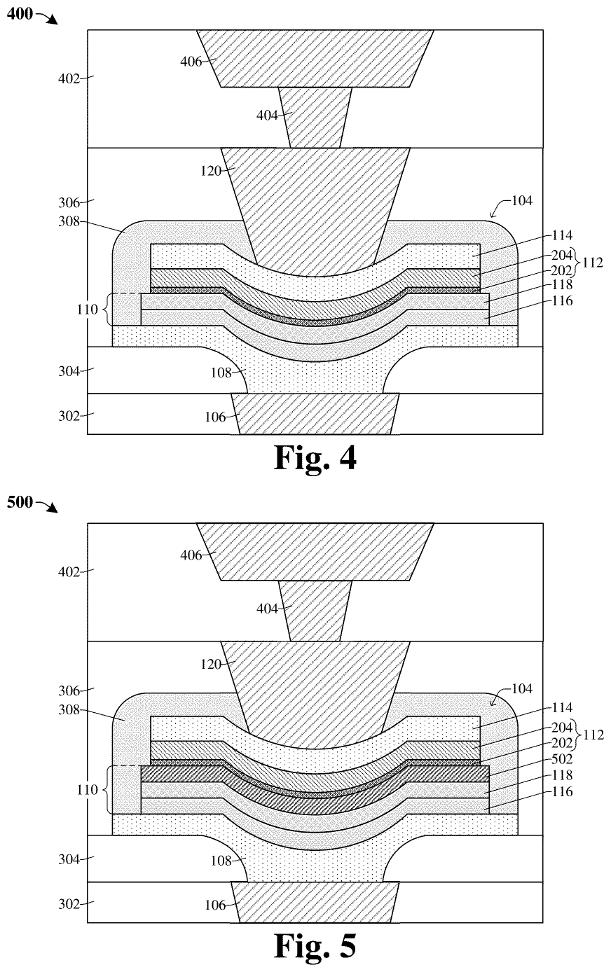

FIG. 4 illustrates a cross-sectional view 400 corresponding to some other embodiments of the integrated chip of FIG. 3, where a third IMD layer 402 overlies the second IMD layer 306. An upper conductive via 404 and an upper conductive wire 406 are disposed within the third IMD layer 402. The upper conductive via and wire 404, 406 are electrically coupled to the RRAM cell 104 by way of the upper conductive structure 120. The upper conductive structure 120 may, for example, be configured as a top electrode via. In various embodiments, the bottom electrode 108 comprises a peripheral region that extends over a top surface of the lower dielectric layer 304 and a middle region that extends through the lower dielectric layer 304. In the middle region the bottom electrode 108 has a curved upper surface over the lower conductive wire 106. Further, layers of the RRAM cell 104 over the bottom electrode 108 respectively conform to a shape of the curved upper surface of the bottom electrode 108. In various embodiments, a bottom surface of the oxygen affinity layer 118 is disposed below a top surface of the bottom electrode 108. Outer sidewalls of the dielectric layer 116 and outer sidewalls of the oxygen affinity layer 118 are spaced between outer sidewalls of the bottom electrode 108. Outer sidewalls of the diffusion barrier layer 202, outer sidewalls of the metal layer 204, and outer sidewalls of the top electrode 114 are spaced between the outer sidewalls of the oxygen affinity layer 118. Further, a bottom surface of the upper conductive structure 120 is disposed below a top surface of the top electrode 114.

FIG. 5 illustrates a cross-sectional view 500 corresponding to some other embodiments of the integrated chip of FIG. 4, where the switching structure 110 of the RRAM cell 104 further comprises an upper oxygen affinity layer 502 disposed between the diffusion barrier layer 202 and the oxygen affinity layer 118.

In some embodiments, a Gibbs free energy of the dielectric layer 116 is greater than a Gibbs free energy of the oxygen affinity layer 118, and the Gibbs free energy of the oxygen affinity layer 118 is greater than a Gibbs free energy of the upper oxygen affinity layer 502. As a result, the upper oxygen affinity layer 502 is more likely to react with oxygen than the oxygen affinity layer 118, such that oxygen ions from the dielectric layer 116 and/or the oxygen affinity layer 118 may migrate to the upper oxygen affinity layer 502. This, in part, may result in the formation of intrinsic oxygen vacancies in both the oxygen affinity layer 118 and the dielectric layer 116, thereby further decreasing the forming voltage of the RRAM cell 104. In some embodiments, a Gibbs free energy of the switching structure 110 discretely decreases at least two times in a direction from a top surface of the bottom electrode 108 towards the top electrode 114.

In various embodiments, the Gibbs free energy of the upper oxygen affinity layer 502 being less than the Gibbs free energy of the oxygen affinity layer 118 facilitates controlling a shape and/or size of a conductive path (not shown) formed in the switching structure 110. In such embodiments, a width of the conductive path in the oxygen affinity layer 118 is greater than the width of the conductive path in the dielectric layer 116, and the width of the conductive path in the upper oxygen affinity layer 502 is greater than the width of the conductive path in the oxygen affinity layer 118. In some embodiments, the Gibbs free energy of the upper oxygen affinity layer 502 is less than −1100 kJ/mol. A first difference between the Gibbs free energy of the oxygen affinity layer 118 and the Gibbs free energy of the dielectric layer 116 is less than or equal to −100 kJ/mol. A second difference between the Gibbs free energy of the upper oxygen affinity layer 502 and the Gibbs free energy of the oxygen affinity layer 118 is less than −100 kJ/mol. In various embodiments, the first difference between the Gibbs free energy of the oxygen affinity layer 118 and the dielectric layer 116 is greater than the second difference between the Gibbs free energy of the upper oxygen affinity layer 502 and the oxygen affinity layer 118. For example, the first difference may be within a range of about −100 kJ/mol to about −250 kJ/mol and the second difference may be within a range of about −500 kJ/mol to about −800 kJ/mol. This, in part, facilitates forming the intrinsic oxygen vacancies in both the oxygen affinity layer 118 and the dielectric layer 116.

The dielectric layer 116 comprises a first dielectric material that may, for example, be or comprise titanium oxide (e.g., TiO), tantalum oxide (e.g., Ta₂O₅), titanium dioxide (e.g., TiO₂), silicon dioxide (e.g., SiO₂), zinc oxide (e.g., ZnO), or some other suitable dielectric material. The oxygen affinity layer 118 comprises a second dielectric material that may, for example, be or comprise zirconium dioxide (e.g., ZrO₂), lanthanum oxide (e.g., La₂O₃), neodymium oxide (e.g., Nd₂O₃), gadolinium oxide (e.g., Gd₂O₃), or some other suitable dielectric material. The upper oxygen affinity layer 502 comprises a third dielectric material that may, for example, be or comprise yttrium oxide (e.g., Y₂O₂), aluminum oxide (e.g., Al₂O₃), or some other suitable dielectric material. The first dielectric material, the second dielectric material, and the third dielectric material are each different from one another. In various embodiments, the dielectric layer 116 consists essentially of titanium dioxide (e.g., TiO₂) and has a Gibbs free energy of about −945 kJ/mol, the oxygen affinity layer 118 consists essentially of zirconium dioxide (e.g., ZrO₂) and has a Gibbs free energy of about −1099 kJ/mol, and the upper oxygen affinity layer 502 consists essentially of yttrium oxide (e.g., Y₂O₂) and has a Gibbs free energy of about −1907 kJ/mol. In such embodiments, the first difference between the Gibbs free energy of the oxygen affinity layer 118 and the dielectric layer 116 is about −150 kJ/mol and the second between the Gibbs free energy of the upper oxygen affinity layer 502 and the oxygen affinity layer 118 is about −800 kJ/mol. In yet further embodiments, the dielectric layer 116, the oxygen affinity layer 118, and the upper oxygen affinity layer 502 are each undoped.

In yet further embodiments, a thickness of the upper oxygen affinity layer 502 is equal to or less than a thickness of the dielectric layer 116. The thickness of the upper oxygen affinity layer 502 may, for example, be within a range of about 10 to 15 angstroms or some other suitable value. In yet further embodiments, the thickness of the upper oxygen affinity layer 502 is equal to or less than the thickness of the oxygen affinity layer 118.

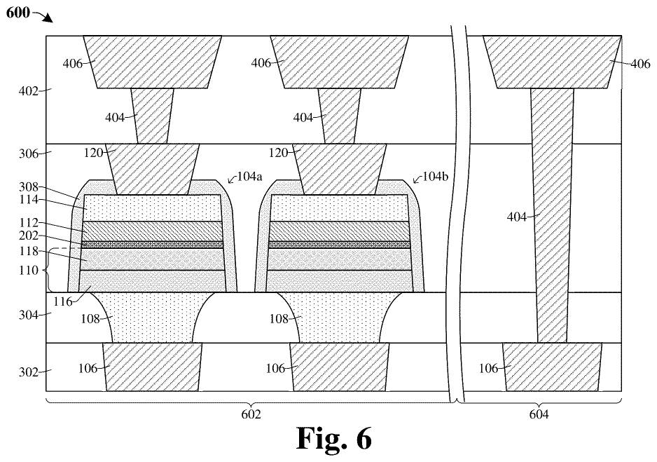

FIG. 6 illustrates a cross-sectional view 600 of some embodiments of an integrated chip comprising a memory region 602 laterally adjacent to a logic region 604. The integrated chip comprises a first RRAM cell 104a and a second RRAM cell 104b disposed within the memory region 602. In some embodiments, the first and second RRAM cells 104a, 104b are respectively configured as illustrated and/or described in FIG. 3. An upper conductive via 404 disposed within the logic region 604 and continuously extends from an upper conductive wire 406 to a lower conductive wire 106 in the logic region 604.

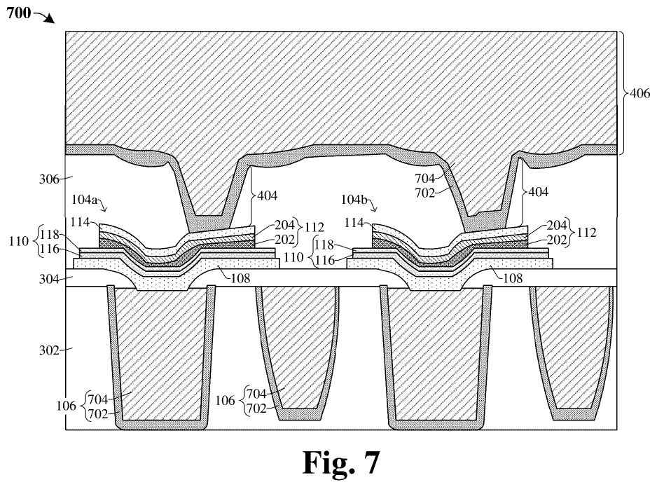

FIG. 7 illustrates a cross-sectional view 700 of some other embodiments of an integrated chip comprising a first RRAM cell 104a and a second RRAM cell 104b laterally adjacent to one another. In some embodiments, the first and second RRAM cells 104a, 104b are respectively configured as illustrated and/or described in FIGS. 3, 4, or 6.

The integrated chip comprises a plurality of lower conductive wires 106 underlying the first and second RRAM cells 104a, 104b. A plurality of upper conductive vias 404 and an upper conductive wire 406 overlie the first and second RRAM cells 104a, 104b. The plurality of lower conductive wires 106, the plurality of upper conductive vias 404, and the upper conductive wire 406 respectively comprise a conductive body 704 and a conductive liner layer 702. In some embodiments, the conductive liner layer 702 extends along a lower surface and opposing sidewalls of the conductive body 704. The conductive body 704 may, for example, be or comprise copper, aluminum, tungsten, ruthenium, another conductive material, or any combination of the foregoing. The conductive liner layer 702 may, for example, be or comprise titanium nitride, tantalum nitride, or the like. In various embodiments, the upper conductive wire 406 continuously laterally extends from over the first RRAM cell 104a to over the second RRAM cell 104b. Layers in the first and second RRAM cells 104a, 104b respectively have a protrusion segment extending downward towards a corresponding lower conductive wire 106. In various embodiments, the upper conductive vias 404 are laterally offset from the protrusion segment of the layers of the first and second RRAM cells 104a, 104b.

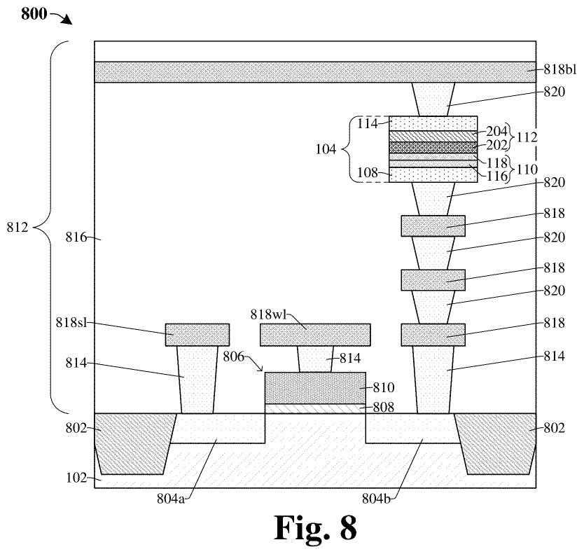

FIG. 8 illustrates a cross-sectional view 800 of an integrated chip having an RRAM cell 104 disposed within an interconnect structure 812 that overlies a substrate 102. In some embodiments, the RRAM cell 104 of FIG. 8 may be configured as the RRAM cell 104 of any one of FIGS. 1-7.

The integrated chip of FIG. 8 includes a semiconductor device 806 disposed on the substrate 102. The semiconductor device 806 may, for example, be a metal-oxide semiconductor field-effect transistor (MOSFET), a bipolar junction transistor (BTJ), a high-electric-mobility transistor (HEMT), any other front-end-of-line semiconductor device, or the like. The semiconductor device 806 comprises a gate dielectric layer 808, a gate electrode 810 overlying the gate dielectric layer 808, and a pair of source/drain regions 804a-b. An isolation structure 802 is disposed within the substrate 102 and is configured to electrically isolate the semiconductor device 806 from other devices (not shown) disposed within and/or on the substrate 102. Source/drain region(s) may refer to a source or a drain, individually or collectively dependent upon the context.

An interconnect structure 812 is disposed over the substrate 102 and the semiconductor device 806. In some embodiments, the interconnect structure 812 comprises an interconnect dielectric structure 816, a plurality of conductive contacts 814, a plurality of conductive lines 818 (e.g., metal lines), and a plurality of conductive vias 820 (e.g., metal vias). The plurality of conductive contacts 814, the plurality of conductive lines 818, and the plurality of conductive vias 820 are electrically coupled in a predefined manner and configured to provide electrical connections between various devices disposed throughout the integrated chip. In further embodiments, the plurality of conductive contacts 814, the plurality of conductive lines 818, and/or the plurality of conductive vias 820 may, for example, respectively be or comprise titanium nitride, tantalum nitride, tungsten, ruthenium, aluminum, copper, another conductive material, or any combination of the foregoing. In yet further embodiments, the interconnect dielectric structure 816 may comprises one or more ILD layers, which may respectively comprise a low-k dielectric material, an oxide (e.g., silicon dioxide), another dielectric material, or any combination of the foregoing. The RRAM cell 104 comprises the bottom electrode 108, the switching structure 110, the capping structure 112, and the top electrode 114. In various embodiments, the switching structure 110 comprises the dielectric layer 116 and the oxygen affinity layer 118, and the capping structure 112 comprises the diffusion barrier layer 202 and the metal layer 204.

A first one of the plurality of conductive lines 818 is denoted as 818wl and may be referred to as a word line. In some embodiments, the word line 818wl may be electrically coupled to the gate electrode 810 of the semiconductor device 806 via the interconnect structure 812. A second one of the plurality of conductive lines 818 is denoted as 818sl and may be referred to as a source line. In further embodiments, the source line 818sl may be electrically coupled to a first source/drain region 804a of the semiconductor device 806 via the interconnect structure 812. A third one of the plurality of conductive lines 818 is denoted as 818bl and may be referred to as a bit line. In yet further embodiments, the bit line 818bl may be electrically coupled to the top electrode 114 of the RRAM cell 104 and the bottom electrode 108 may be electrically coupled to a second source/drain region 804b of the semiconductor device 806 via the interconnect structure 812.

In some embodiments, the RRAM cell 104 is electrically coupled to a second source/drain region 804b of the semiconductor device 806 via the interconnect structure 812. Thus, in some embodiments, application of a suitable word line voltage to the word line 818wl may electrically couple the RRAM cell 104 between the bit line 818bl and the source line 818sl. Consequently, by providing suitable bias conditions, the RRAM cell 104 can be switched between two data states.

FIGS. 9-14 illustrate cross-sectional views 900-1400 of some embodiments of a method of forming an integrated chip including an RRAM cell comprising a switching layer having an oxygen affinity layer stacked with a dielectric layer according to the present disclosure. Although the cross-sectional views 900-1400 shown in FIGS. 9-14 are described with reference to a method, it will be appreciated that the structures shown in FIGS. 9-14 are not limited to the method but rather may stand alone separate of the method. Although FIGS. 9-14 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in cross-sectional view 900 of FIG. 9, a first inter-metal dielectric (IMD) layer 302 is formed over a substrate 102 and a lower conductive wire 106 is formed within the first IMD layer 302. The substrate 102 may, for example, be or comprise silicon, monocrystalline silicon, silicon-germanium, a silicon-on-insulator (SOI) substrate, one or more epitaxial layers, some other suitable substrate or any combination of the foregoing. The first IMD layer 302 may be formed over the substrate 102 by, for example, a chemical vapor deposition (CVD) process, a physical vapor deposition (PVD) process, an atomic layer deposition (ALD) process, or some other suitable growth or deposition process. In some embodiments, the lower conductive wire 106 is formed by etching the first IMD layer 302 to form an opening in the first IMD layer 302 and depositing (e.g., by PVD, CVD, sputtering, electroplating, electroless plating, etc.) the lower conductive wire 106 in the opening.

In addition, a lower dielectric layer 304 is formed over the lower conductive wire 106 and a bottom electrode 108 is formed within the lower dielectric layer 304. The lower dielectric layer 304 may be formed over the lower conductive wire 106 by, for example, a CVD process, a PVD process, an ALD process, or some other suitable growth or deposition process. In some embodiments, a process for forming the bottom electrode 108 includes: forming a masking layer (not shown) over the lower dielectric layer 304; etching (e.g., a wet etch, a dry etch, etc.) the lower dielectric layer 304 to form an opening over the lower conductive wire 106; depositing (e.g., by PVD, CVD, sputtering, electroplating, etc.) a bottom electrode material within the opening; and performing a planarization process (e.g., a chemical mechanical polishing (CMP) process) on the bottom electrode material.

The first IMD layer 302 may, for example, be or comprise silicon dioxide, a low-k dielectric material such as undoped silica glass (USG) or carbon-doped silicon dioxide, some other suitable dielectric material, or any combination of the foregoing. The lower conductive wire 106 may, for example, be or comprise aluminum, copper, tungsten, ruthenium, titanium nitride, some other suitable conductive material, or any combination of the foregoing. The lower dielectric layer 304 may, for example, be or comprise silicon carbide, silicon oxycarbide, silicon nitride, silicon oxynitride, some other dielectric material, or any combination of the foregoing. The bottom electrode 108 may, for example, be or comprise titanium, tantalum, platinum, nickel, hafnium, ruthenium, iridium, another conductive material, or any combination of the foregoing.

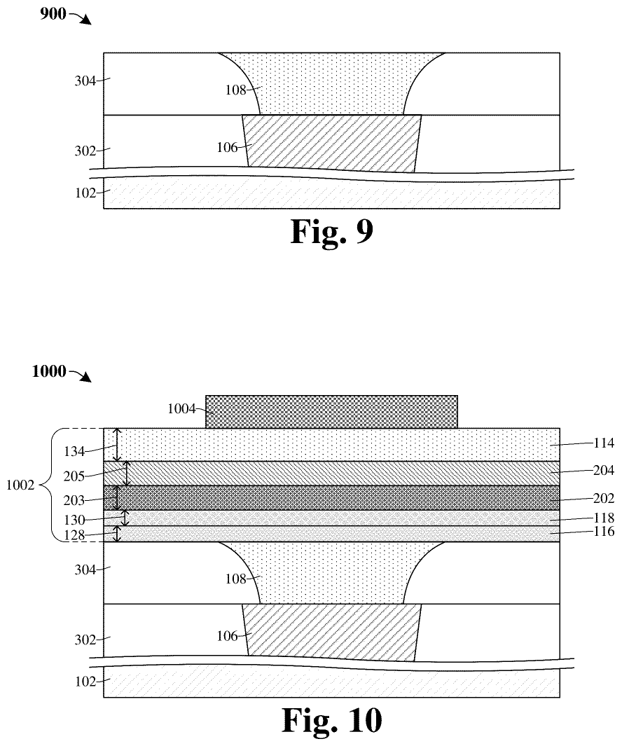

As shown in cross-sectional view 1000 of FIG. 10, a stack of memory layers 1002 is formed over the bottom electrode 108 and a masking layer 1004 is formed over the stack of memory layers 1002. In some embodiments, the stack of memory layers 1002 includes: a dielectric layer 116, an oxygen affinity layer 118, a diffusion barrier layer 202, a metal layer 204, and a top electrode 114. In various embodiments, layers within the stack of memory layers 1002 are respectively formed by a CVD process, a PVD process, an ALD process, an electroplating process, an electroless plating process, or another suitable growth or deposition process. The masking layer 1004 is formed such that the masking layer 1004 covers a middle region (e.g., overlying the bottom electrode 108) of the stack of memory layers 1002 and leaves a peripheral region of the stack of memory layers 1002 exposed.

In some embodiments, the dielectric layer 116 may, for example, be or comprise titanium oxide (e.g., TiO), tantalum oxide (e.g., Ta₂O₅), titanium dioxide (e.g., TiO₂), silicon dioxide (e.g., SiO₂), Zinc Oxide (e.g., ZnO), or some other suitable dielectric material. In further embodiments, the oxygen affinity layer 118 may, for example, be or comprise zirconium dioxide (e.g., ZrO₂), lanthanum oxide (e.g., La₂O₃), neodymium oxide (e.g., Nd₂O₃), gadolinium oxide (e.g., Gd₂O₃), Yttrium Oxide (e.g., Y₂O₂), or some other suitable dielectric material. In various embodiments, a Gibbs free energy of the dielectric layer 116 is greater than at least −1000 kJ/mol and a Gibbs free energy of the oxygen affinity layer 118 is less than at least −1000 kJ/mol. By virtue of the difference in Gibbs free energy between the dielectric layer 116 and the oxygen affinity layer 118, the oxygen affinity layer 118 is configured to form intrinsic oxygen vacancies (not shown) in the dielectric layer 116 before performing a formation operation and a write operation on the dielectric layer 116. In various embodiments, the intrinsic oxygen vacancies are formed within the dielectric layer 116 before forming the diffusion barrier layer 202 over the oxygen affinity layer 118.

The diffusion barrier layer 202 may, for example, be or comprise tantalum nitride, titanium nitride, hafnium nitride, zirconium nitride, some other suitable material, or any combination of the foregoing. The metal layer 204 may, for example, be or comprise tantalum, titanium, hafnium, zirconium, some other suitable material, or any combination of the foregoing. The top electrode 114 may, for example, be or comprise titanium nitride, tantalum nitride, tantalum, titanium, platinum, nickel, hafnium, zirconium, ruthenium, iridium, some other suitable conductive material, or any combination of the foregoing.

A thickness 128 of the dielectric layer 116 is, for example, within a range of about 10 to 15 angstroms or some other suitable value. A thickness 130 of the oxygen affinity layer 118 is, for example, within a range of about 10 to 15 angstroms or some other suitable value. A thickness 203 of the diffusion barrier layer 202 is, for example, within a range of about 20 to 30 angstroms or some other suitable value. A thickness 205 of the metal layer 204 is, for example, within a range of about 10 to 50 angstroms or some other suitable value. A thickness 134 of the top electrode 114 is, for example, within a range of about 80 to 195 angstroms or some other suitable value. In various embodiments, ratios of thicknesses between layers in the stack of memory layers 1002 are configured as illustrated and/or described in FIGS. 1 and/or 2. In further embodiments, the stack of memory layers 1002 further comprises an upper oxygen affinity layer (not shown) disposed between the oxygen affinity layer 118 and the diffusion barrier layer 202. The upper oxygen affinity layer may be configured as illustrated and/or described in FIG. 5. In such embodiments, the upper oxygen affinity layer is formed by a CVD process, a PVD process, an ALD process, or some other suitable growth or deposition process.

As shown in cross-sectional view 1100 of FIG. 11, a patterning process is performed on the stack of memory layers (1002 of FIG. 10), thereby defining a switching structure 110, a capping structure 112, and an RRAM cell 104. In various embodiments, the switching structure 110 includes the dielectric layer 116 and the oxygen affinity layer 118, and the capping structure 112 comprises the diffusion barrier layer 202 and the metal layer 204. In some embodiments, the patterning process includes exposing unmasked regions (e.g., in the peripheral region) of the layers in the stack of memory layers (1002 of FIG. 10) to one or more etchants. The patterning process may, for example, comprise one or more dry etching processes, one or more wet etching processes, or the like. Further, the masking layer (1004 of FIG. 10) may be removed during and/or after the patterning process.

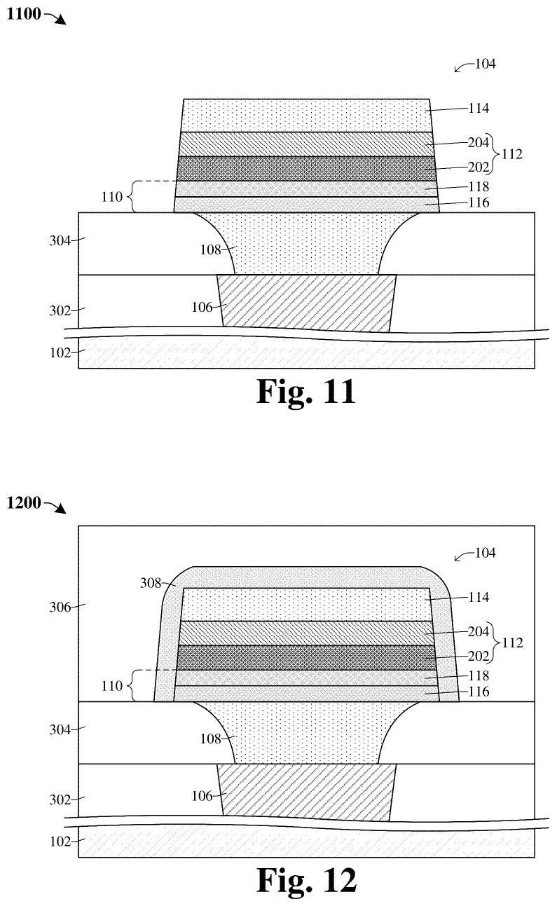

As shown in cross-sectional view 1200 of FIG. 12, a sidewall spacer structure 308 is formed over and around the RRAM cell 104, and a second IMD layer 306 is formed over the sidewall spacer structure 308 and the lower dielectric layer 304. The sidewall spacer structure 308 may be formed over the RRAM cell 104 by, for example, a CVD process, a PVD process, an ALD process, or some other suitable growth or deposition process. The second IMD layer 306 may be formed over the lower dielectric layer 304 by, for example, a CVD process, a PVD process, an ALD process, or some other suitable growth or deposition process. The sidewall spacer structure 308 may, for example, be or comprise silicon nitride, silicon oxynitride, silicon carbide, silicon oxycarbide, another dielectric material, or any combination of the foregoing. The second IMD layer 306 may, for example, be or comprise silicon dioxide, a low-k dielectric material such as USG or carbon-doped silicon dioxide, some other suitable dielectric material, or any combination of the foregoing.

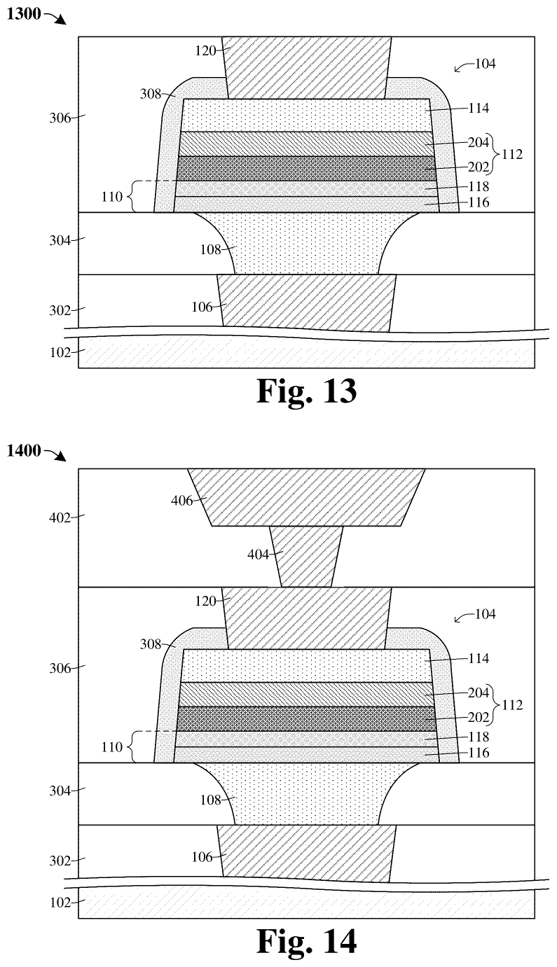

As shown in cross-sectional view 1300 of FIG. 13, an upper conductive structure 120 is formed over the top electrode 114. In some embodiments, a process for forming the upper conductive structure 120 includes: depositing a masking layer (not shown) over the second IMD layer 306; patterning the second IMD layer 306 and the sidewall spacer structure 308 according to the masking layer, thereby forming an opening over the top electrode 114; depositing (e.g., by CVD, PVD, sputtering, electroplating, electroless plating, etc.) a conductive material (e.g., comprising aluminum, copper, titanium, tantalum, titanium nitride, tantalum nitride, etc.) in the opening; and performing a planarization process (e.g., a CMP process) on the conductive material.

As shown in cross-sectional view 1400 of FIG. 14, a third IMD layer 402 is formed over the second IMD layer 306, and an upper conductive via 404 and an upper conductive wire 406 are formed within the third IMD layer 402. The third IMD layer 402 is formed over the second IMD layer 306 by, for example, a CVD process, a PVD process, an ALD process, or some other suitable deposition or growth process. In some embodiments, forming the upper conductive via 404 and the upper conductive wire 406 includes: etching the third IMD layer 402 to form one or more openings in the third IMD layer 402; depositing (e.g., by CVD, PVD, ALD, sputtering, electro plating, etc.) a conductive material (e.g., aluminum, copper, titanium nitride, tantalum nitride, ruthenium, etc.) in the one or more openings, and performing a planarization process (e.g., a CMP process) on the conductive material. The third IMD layer 402 may, for example, be or comprise silicon dioxide, a low-k dielectric material such as USG or carbon-doped silicon dioxide, some other suitable dielectric material, or any combination of the foregoing.

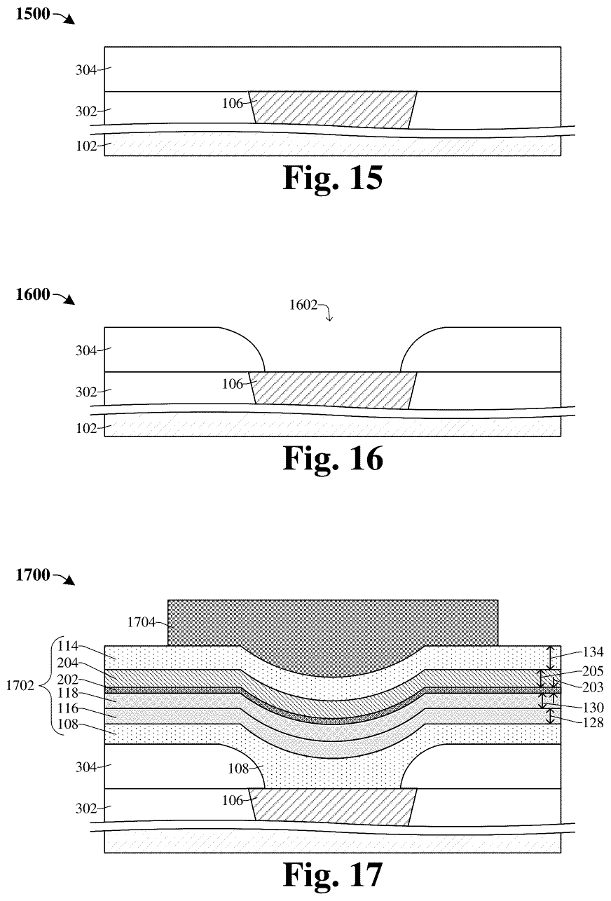

FIGS. 15-22 illustrate cross-sectional views 1500-2200 of some other embodiments of a method of forming an integrated chip including an RRAM cell comprising a switching layer having an oxygen affinity layer stacked with a dielectric layer according to the present disclosure. Although the cross-sectional views 1500-2200 shown in FIGS. 15-22 are described with reference to a method, it will be appreciated that the structures shown in FIGS. 15-22 are not limited to the method but rather may stand alone separate of the method. Although FIGS. 15-22 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in cross-sectional view 1500 of FIG. 15, a first inter-metal dielectric (IMD) layer 302 is formed over a substrate 102 and a lower conductive wire 106 is formed within the first IMD layer 302. In some embodiments, the first IMD layer 302 and the lower conductive wire 106 are formed as illustrated and/or described in FIG. 9. Further, a lower dielectric layer 304 is formed over the lower conductive wire 106. The lower dielectric layer 304 may be formed over the lower conductive wire 106 by, for example, a CVD process, a PVD process, an ALD process, or some other suitable process.

As shown in cross-sectional view 1600 of FIG. 16, a patterning process is performed on the lower dielectric layer 304 to form an opening 1602 in the lower dielectric layer 304. In some embodiments, the patterning process includes forming a masking layer (not shown) over the lower dielectric layer 304 and exposing unmasked regions of the lower dielectric layer 304 to one or more etchants. The patterning process may, for example, comprise a wet etch process, a dry etch process, or the like.

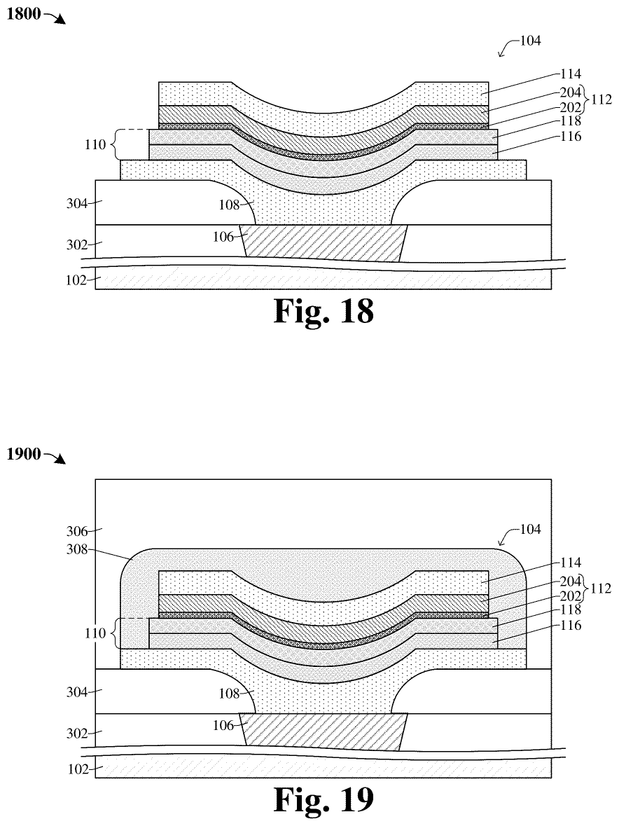

As shown in cross-sectional view 1700 of FIG. 17, a stack of memory layers 1702 is formed over the lower conductive wire 106 and the lower dielectric layer 304, thereby filling the opening (1602 of FIG. 16). In some embodiments, the stack of memory layers 1702 includes: a bottom electrode 108, a dielectric layer 116, an oxygen affinity layer 118, a diffusion barrier layer 202, a metal layer 204, and a top electrode 114. In various embodiments, layers within the stack of memory layers 1702 are respectively formed by a CVD process, a PVD process, an ALD process, an electroplating process, an electroless plating process, or another suitable growth or deposition process. Further, layers of the stack of memory layers 1702 are formed such that the layers conform to a shape of opposing sidewalls of the lower dielectric layer 304 that define the opening (1602 of FIG. 16). Further, a masking layer 1704 is formed over a middle region of the stack of memory layers 1702, where the masking layer 1704 leaves a peripheral region of the stack of memory layers 1702 exposed.

In some embodiments, thicknesses of layers in the stack of memory layers 1702 are configured as illustrated and/or described in FIG. 10. In further embodiments, the stack of memory layers 1702 further comprises an upper oxygen affinity layer (not shown) disposed between the oxygen affinity layer 118 and the diffusion barrier layer 202. The upper oxygen affinity layer may be configured as illustrated and/or described in FIG. 5. In such embodiments, the upper oxygen affinity layer is formed by a CVD process, a PVD process, an ALD process, or some other suitable growth or deposition process.

As shown in cross-sectional view 1800 of FIG. 18, a patterning process is performed on the stack of memory layers (1702 of FIG. 17), thereby defining a switching structure 110, a capping structure 112, and an RRAM cell 104. In various embodiments, the switching structure 110 includes the dielectric layer 116 and the oxygen affinity layer 118, and the capping structure 112 comprises the diffusion barrier layer 202 and the metal layer 204. In some embodiments, the patterning process includes exposing unmasking regions (e.g., in the peripheral region) of the layers in the stack of memory layers (1702 of FIG. 17) to one or more etchants. The patterning process may, for example, comprise one or more dry etching process, one or more wet etching process, or the like. Further, the masking layer (1704 of FIG. 17) may be removed during and/or after the patterning process.

As shown in cross-sectional view 1900 of FIG. 19, a sidewall spacer structure 308 is formed over and around the RRAM cell 104, and a second IMD layer 306 is formed over the sidewall spacer structure 308 and the lower dielectric layer 304. The sidewall spacer structure 308 may be formed over the RRAM cell 104 by, for example, a CVD process, a PVD process, an ALD process, or some other suitable growth or deposition process. The second IMD layer 306 may be formed over the lower dielectric layer 304 by, for example, a CVD process, a PVD process, an ALD process, or some other suitable growth or deposition process.

As shown in cross-sectional view 2000 of FIG. 20, an upper conductive structure 120 is formed over the top electrode 114. In some embodiments, a process for forming the upper conductive structure 120 includes: depositing a masking layer (not shown) over the second IMD layer 306; patterning the second IMD layer 306 and the sidewall spacer structure 308 according to the masking layer, thereby forming an opening over the top electrode 114; depositing (e.g., by CVD, PVD, sputtering, electroplating, electroless plating, etc.) a conductive material (e.g., comprising aluminum, copper, titanium, tantalum, titanium nitride, tantalum nitride, etc.) in the opening; and performing a planarization process (e.g., a CMP process) on the conductive material.

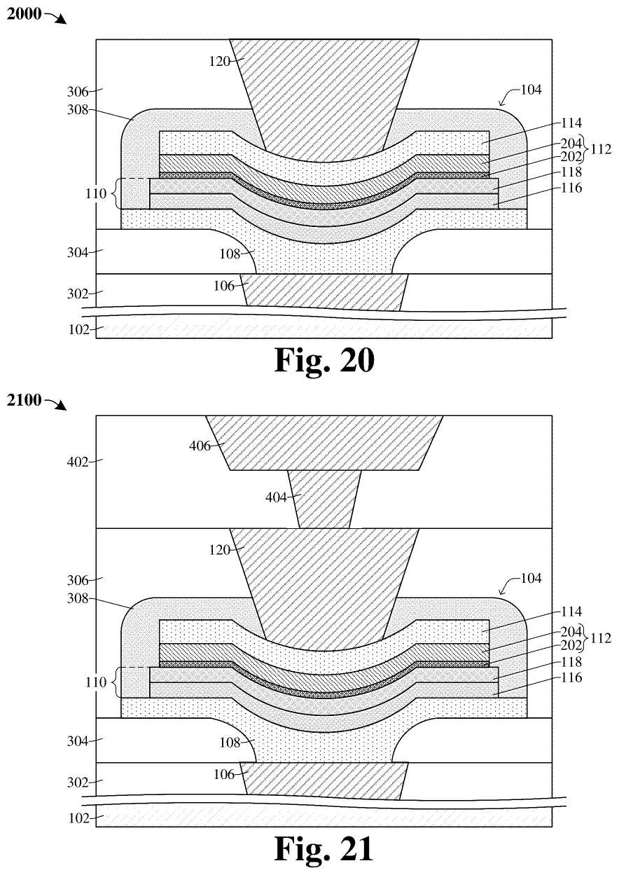

As shown in cross-sectional view 2100 of FIG. 21, a third IMD layer 402 is formed over the second IMD layer 306, and an upper conductive via 404 and an upper conductive wire 406 are formed within the third IMD layer 402. The third IMD layer 402 is formed over the second IMD layer 306 by, for example, a CVD process, a PVD process, an ALD process, or some other suitable deposition or growth process. In some embodiments, forming the upper conductive via 404 and the upper conductive wire 406 includes: etching the third IMD layer 402 to form one or more openings in the third IMD layer 402; depositing (e.g., by CVD, PVD, ALD, sputtering, electro plating, etc.) a conductive material (e.g., aluminum, copper, titanium nitride, tantalum nitride, ruthenium, etc.) in the one or more openings, and performing a planarization process (e.g., a CMP process) on the conductive material.

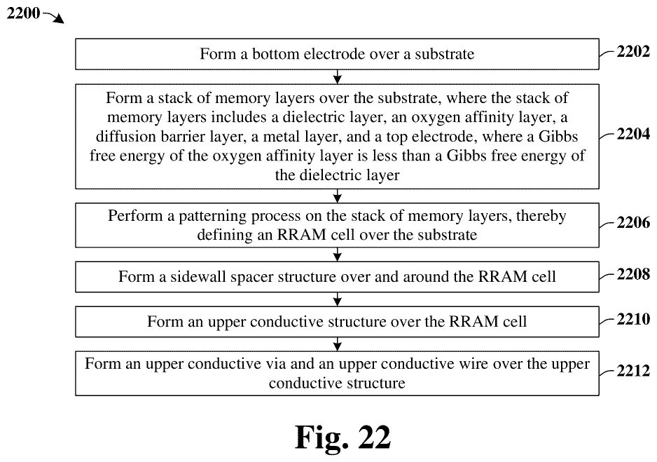

FIG. 22 illustrates a method 2200 of forming an integrated chip including an RRAM cell comprising a switching layer having an oxygen affinity layer stacked with a dielectric layer according to the present disclosure. Although the method 2200 is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 2202, a bottom electrode is formed over a substrate. FIG. 9 illustrates the cross-sectional view 900 corresponding to some embodiments of act 2202. FIG. 17 illustrates the cross-sectional view 1700 corresponding to some other embodiments of act 2202.

At act 2204, a stack of memory layers is formed over the substrate, where the stack of memory layers includes a dielectric layer, an oxygen affinity layer, a diffusion barrier layer, a metal layer, and atop electrode, where a Gibbs free energy of the oxygen affinity layer is less than a Gibbs free energy of the dielectric layer. FIG. 10 illustrates the cross-sectional view 1000 corresponding to some embodiments of act 2204. FIG. 17 illustrates the cross-sectional view 1700 corresponding to some other embodiments of act 2204.

At act 2206, a patterning process is performed on the stack of memory layers, thereby defining an RRAM cell over the substrate. FIG. 11 illustrates the cross-sectional view 1100 corresponding to some embodiments of act 2206. FIG. 18 illustrates the cross-sectional view 1800 corresponding to some other embodiments of act 2206.

At act 2208, a sidewall spacer structure is formed over and around the RRAM cell. FIG. 12 illustrates the cross-sectional view 1200 corresponding to some embodiments of act 2208. FIG. 19 illustrates the cross-sectional view 1900 corresponding to some other embodiments of act 2208.

At act 2210, an upper conductive structure is formed over the RRAM cell. FIG. 13 illustrates the cross-sectional view 1300 corresponding to some embodiments of act 2210. FIG. 20 illustrates the cross-sectional view 2000 corresponding to some other embodiments of act 2210.

At act 2212, an upper conductive via and an upper conductive wire are formed over the upper conductive structure. FIG. 14 illustrates the cross-sectional view 1400 corresponding to some embodiments of act 2212. FIG. 21 illustrates the cross-sectional view 2100 corresponding to some other embodiments of act 2212.

Accordingly, in some embodiments, the present disclosure relates to an RRAM cell comprising a switching structure disposed between a bottom electrode and a top electrode. The switching structure comprises an oxygen affinity layer overlying a dielectric layer, where a Gibbs free energy of the oxygen affinity layer is less than a Gibbs free energy of the dielectric layer.

In some embodiments, the present application provides an integrated chip including: a bottom electrode overlying a substrate; a top electrode over the bottom electrode; a capping structure disposed between the top electrode and the bottom electrode, wherein the capping structure comprises a diffusion barrier layer vertically stacked with a metal layer; and a switching structure disposed between the bottom electrode and the capping structure, wherein the switching structure comprises a dielectric layer on the bottom electrode and a first oxygen affinity layer on the dielectric layer, wherein a first Gibbs free energy of the first oxygen affinity layer is less than a second Gibbs free energy of the dielectric layer, and wherein a first difference between the first Gibbs free energy and the second Gibbs free energy is less than −100 kJ/mol.

In some embodiments, the present application provides an integrated chip including: a first conductive structure over a substrate; a second conductive structure over the first conductive structure, wherein the second conductive structure includes a top electrode over a capping structure; and a switching structure located between the first conductive structure and the capping structure, wherein the switching structure comprises a dielectric layer on the first conductive structure and a first oxygen affinity layer on the dielectric layer, wherein a first Gibbs free energy of the first oxygen affinity layer is less than −1000 kJ/mol, wherein a thickness of the dielectric layer is greater than or equal to a thickness of the first oxygen affinity layer, wherein a ratio of a thickness of the switching structure and a thickness of the second conductive structure is within a range of 0.1 to 0.2, and wherein a ratio of the thickness of the switching structure and a thickness of the first conductive structure is within a range of 0.2 to 0.3.

In some embodiments, the present application provides a method for forming an integrated chip, the method includes: forming a lower conductive wire over a substrate; forming a stack of memory layers over the lower conductive wire, wherein the stack of memory layers comprises a dielectric layer, a first oxygen affinity layer over the dielectric layer, a diffusion barrier layer over the first oxygen affinity layer, a metal layer over the diffusion barrier layer, and a top electrode over the metal layer, wherein a first Gibbs free energy of the first oxygen affinity layer is less than a second Gibbs free energy of the dielectric layer, and wherein a first difference between the first Gibbs free energy and the second Gibbs free energy is less than −100 kJ/mol; forming a masking layer over the stack of memory layers; and patterning the stack of memory layers according to the masking layer, thereby defining a memory cell.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip, comprising:
a bottom electrode overlying a substrate;
a top electrode over the bottom electrode;
a capping structure disposed between the top electrode and the bottom electrode, wherein the capping structure comprises a diffusion barrier layer vertically stacked with a metal layer; and
a switching structure disposed between the bottom electrode and the capping structure, wherein the switching structure comprises a dielectric layer on the bottom electrode and a first oxygen affinity layer on the dielectric layer, wherein a first Gibbs free energy of the first oxygen affinity layer is less than a second Gibbs free energy of the dielectric layer, and wherein a first difference between the first Gibbs free energy and the second Gibbs free energy is less than −100 kJ/mol.

2. The integrated chip of claim 1, wherein the first Gibbs free energy is less than −1,000 kJ/mol and the second Gibbs free energy is greater than −1,000 kJ/mol.

3. The integrated chip of claim 1, wherein a ratio of a thickness of the first oxygen affinity layer and a thickness of the dielectric layer is within a range of 0.85 to 1.

4. The integrated chip of claim 3, wherein a ratio of a thickness of the switching structure and a thickness of both the top electrode and the capping structure is within a range of 0.1 to 0.2.

5. The integrated chip of claim 4, wherein a ratio of the thickness of the switching structure and a thickness of the bottom electrode is within a range of 0.2 to 0.3, wherein the thickness of the bottom electrode is less than a thickness of the top electrode.

6. The integrated chip of claim 1, wherein the dielectric layer consists essentially of titanium dioxide and the first oxygen affinity layer consists essentially of zirconium oxide, and wherein the dielectric layer and the first oxygen affinity layer are undoped.

7. The integrated chip of claim 1, wherein the dielectric layer directly contacts the bottom electrode, the first oxygen affinity layer directly contacts the dielectric layer, the diffusion barrier layer directly contacts the first oxygen affinity layer, and the metal layer directly contacts the diffusion barrier layer.

8. The integrated chip of claim 1, wherein the switching structure further comprises:
a second oxygen affinity layer disposed between the first oxygen affinity layer and the diffusion barrier layer, wherein a third Gibbs free energy of the second oxygen affinity layer is less than the first Gibbs free energy, wherein a second difference between the third Gibbs free energy and the first Gibbs free energy is less than the first difference.

9. The integrated chip of claim 8, wherein the second difference is less than −150 kJ/mol.

10. An integrated chip, comprising:
a first conductive structure over a substrate;
a second conductive structure over the first conductive structure, wherein the second conductive structure includes a top electrode over a capping structure; and
a switching structure located between the first conductive structure and the capping structure, wherein the switching structure comprises a dielectric layer on the first conductive structure and a first oxygen affinity layer on the dielectric layer, wherein a first Gibbs free energy of the first oxygen affinity layer is less than −1000 kJ/mol, wherein a thickness of the dielectric layer is greater than or equal to a thickness of the first oxygen affinity layer, wherein a ratio of a thickness of the switching structure and a thickness of the second conductive structure is within a range of 0.1 to 0.2, and wherein a ratio of the thickness of the switching structure and a thickness of the first conductive structure is within a range of 0.2 to 0.3.

11. The integrated chip of claim 10, wherein the capping structure comprises a metal layer vertically stacked with a diffusion barrier layer, wherein the diffusion barrier layer directly contacts the first oxygen affinity layer and the metal layer directly contacts the diffusion barrier layer, wherein the metal layer comprises a metal and the diffusion barrier layer comprises a metal nitride of the metal.

12. The integrated chip of claim 10, wherein the first oxygen affinity layer is configured to form intrinsic oxygen vacancies in the dielectric layer before performing a formation operation and a write operation on the switching structure.

13. The integrated chip of claim 10, wherein the thickness of the dielectric layer is within a range of 10 to 15 angstroms, wherein the thickness of the first oxygen affinity layer is within a range of 10 to 15 angstroms, wherein the thickness of the second conductive structure is within a range of 125 to 275 angstroms, wherein the thickness of the first conductive structure is within a range of 75 to 90 angstroms.

14. The integrated chip of claim 10,
a second oxygen affinity layer disposed between the first oxygen affinity layer and the second conductive structure, wherein a first difference between the first Gibbs free energy and a second Gibbs free energy of the dielectric layer is greater than a second difference between a third Gibbs free energy of the second oxygen affinity layer and the first Gibbs free energy.

15. The integrated chip of claim 14, wherein the first difference is about −150 kJ/mol and the second difference is about −800 kJ/mol.

16. The integrated chip of claim 10, further comprising:
a sidewall spacer structure disposed around outer sidewalls of the switching structure and outer sidewalls of the second conductive structure, wherein the sidewall spacer structure directly contacts a top surface of the second conductive structure and a top surface of the first oxygen affinity layer; and
an inter-metal dielectric (IMD) layer overlying the sidewall spacer structure and the switching structure.

17. The integrated chip of claim 10, further comprising:
a top electrode via overlying the top electrode, wherein the top electrode via is laterally offset from a middle region of the first and second conductive structures and the switching structure, wherein the middle region of the first and second conductive structures and the switching structure comprise a protrusion extending downward in a direction away from the top electrode via.

18. An integrated chip, comprising:
a conductive interconnect in a dielectric layer over a substrate;
a first electrode over the conductive interconnect;
a first metal oxide layer over the first electrode;
a second metal oxide layer over the first metal oxide layer, wherein a material of the second metal oxide layer is different from a material of the first metal oxide layer;
a capping structure over the second metal oxide layer and comprising a metal layer, wherein a bottom surface of the first metal oxide layer is vertically offset from a bottom surface of the capping structure by a first vertical distance; and
a second electrode over the capping structure, wherein the bottom surface of the capping structure is vertically offset from a top surface of the second electrode by a second vertical distance, wherein a first ratio between the first vertical distance and the second vertical distance is within a range of about 0.1 to 0.2.

19. The integrated chip of claim 18, wherein a second ratio between the first vertical distance and a thickness of the first electrode is greater than the first ratio.

20. The integrated chip of claim 18, wherein the capping structure comprises a diffusion barrier layer between the metal layer and the second metal oxide layer, wherein a thickness of the diffusion barrier layer is greater than a thickness of the first metal oxide layer and greater than a thickness of the second metal oxide layer.
